(19) United States
(12) Patent Application Publication
(10) Pub. No.: US 2007/0128763 A1
(43) Pub. Date: Jun. 7, 2007

(54) Method for forming an organic semiconductor layer, organic semiconductor structure and organic semiconductor apparatus

(75) Inventors: Ken Tomino, Tokyo-To (JP); Shigeru Sugawara, Tokyo-To (JP); Hiroki Maeda, Tokyo-To (JP); Masanao Matsuoka, Tokyo-To (JP)

Correspondence Address: BURR & BROWN, PO BOX 7068, SYRACUSE, NY, 13261-7068, US

(73) Assignee: Dai Nippon Printing Co., Ltd., Shinjuku-ku (JP)

(21) Appl. No.: 11/445,939

(22) Filed: Jun. 2, 2006

(30) Foreign Application Priority Data
Jun. 3, 2005 (JP) 2005-163551

(51) Int. Cl. H01L 51/40

(52) U.S. Cl. 438/99

(57) ABSTRACT

This invention is directed to the provision of a method for organic semiconductor layer formation that can easily form a uniform thin film, by coating, which has good charge mobility and a high level of alignment. The method for organic semiconductor layer formation is characterized by comprising the steps of: forming a coating film in a mixed liquid crystal state using a mixture, which can exhibit a thermotropic mixed liquid crystal phase, prepared by mixing an organic semiconductor material with a solvent; and either cooling the coating film to a temperature at which the coating film does not exhibit any mixed liquid crystal state, or removing the solvent while cooling the coating film, to form an organic semiconductor layer comprising a smectic liquid crystal phase or a crystal phase of the organic semiconductor material.

### FIELD OF THE INVENTION

This invention relates to a method for organic semiconductor layer formation, which can easily form a uniform thin film having good charge mobility and a high level of alignment, an organic semiconductor structure, and an organic semiconductor device. More particularly, the present invention relates to a method for organic semiconductor layer formation, which forms an organic semiconductor layer through a mixed liquid crystal state comprising an organic semiconductor material and a solvent, an organic semiconductor structure, and an organic semiconductor device.

### BACKGROUND ART

Attention has recently been drawn to studies on organic semiconductor structures having an organic semiconductor layer, and application of organic semiconductor structures to various devices has been expected. Devices which are utilizable, for example, in large-area flexible display devices, for example, thin-film transistors (also known as “organic TFTs”), luminescent elements, and solar cells, are being studied for such application.

In order to utilize organic semiconductor structures on a practical level, the organic semiconductor layer should exhibit stable charge mobility in a wide service temperature range, and, at the same time, even thin film should be easily formed in a wide area. If film formation by coating rather than film formation by conventional techniques such as vapor deposition is possible, then an even organic semiconductor layer could easily be formed in a wide area. Mere the fact that an organic semiconductor layer can be formed by coating does not suffice for the formation of a satisfactory organic semiconductor layer, and it is also important that the organic semiconductor layer have stable charge mobility in a wide service temperature range including room temperature (about −40 to +90° C.).

Regarding prior art documents relevant to the present invention, for example, non-patent document 1 reports studies on the formation of an organic semiconductor layer from a mixture prepared by mixing 5,5-bis(4-hexylphenyl)-2,2′-bithiophene (hereinafter abbreviated to “6PTTP6”) as a semiconductor oligomer into an n-xylene solvent. In this method reported in this document, an organic semiconductor layer is formed using a concentration induction-type mixed crystal, that is, by mixing 6PTTP6 with n-xylene to provide a lyotropic liquid crystal state and aligning liquid crystal molecules while vaporizing the solvent.

Non-patent document 1: H. K. Katz, T. Sigrist, et al., J. Phys. Chem., B 2004, 108, p. 8567-8571

### DISCLOSURE OF THE INVENTION

### Problems to be Solved by the Invention

The present invention has been made with a view to meeting the above demands, and an object of the present invention is to provide a method for organic semiconductor layer formation that can easily form a uniform thin film having good charge mobility and a high level of alignment by coating. Another object of the present invention is to provide an organic semiconductor structure and an organic semiconductor device having the organic semiconductor layer formed by this method.

### Means for Solving the Problems

The above object of the present invention can be attained by a method for the formation of an organic semiconductor layer, characterized by comprising the steps of:
forming a coating film in a mixed liquid crystal state using an organic semiconductor material and a solvent a mixture, which when mixed together, form a thermotropic mixed liquid crystal phase; and
either cooling the coating film to a temperature at which the coating film does not form any mixed liquid crystal state, or removing the solvent while cooling the coating film, to form an organic semiconductor layer comprising a smectic liquid crystal phase or a crystal phase of said organic semiconductor material.

According to this invention, since a coating film in a mixed liquid crystal state is formed using a mixture, which can exhibit a thermotropic mixed liquid crystal phase, prepared by mixing an organic semiconductor material with a solvent, upon subsequent cooling, a well aligned smectic liquid crystal phase or liquid crystal phase of an organic semiconductor material can be evenly and easily formed. Consequently, the formed organic semiconductor layer can exhibit good charge mobility. According to this method, even for low molecular compounds and high molecular compounds, from which an organic semiconductor layer could not have hitherto been formed by coating without difficulties, the organic semiconductor layer can be formed in good molecule alignment by forming a coating film in a mixed liquid crystal state, and, thus, an organic semiconductor layer, which can exhibit stable charge mobility in a wide service temperature range including room temperature (about −40 to +90° C.; the same shall apply hereinafter), can easily be formed.

The method for the formation of an organic semiconductor layer formation according to the present invention is characterized in that the coating film is formed by heating the above mixture and coating the heated mixture. According to this invention, since the mixture is coated after heating, an even coating film in a mixed liquid crystal state can easily be formed.

In the method for the formation of an organic semiconductor layer according to the present invention, the solvent is preferably one or at least two aromatic solvents selected from xylene, toluene, mesitylene, tetralin, monochlorobenzene, o-dichlorobenzene and the like. Aromatic solvents such as xylene, toluene, mesitylene, tetralin, monochlorobenzene, and o-dichlorobenzene are considered to form the mixed liquid crystal phase through interaction with a skeleton of a π conjugated system possessed by the organic semiconductor material.

Further, the above object of the present invention can be attained by an organic semiconductor structure characterized by comprising an organic semiconductor layer having a smectic liquid crystal phase or a crystal phase at least in a room temperature region, said organic semiconductor layer having been formed by the above method according to the present invention.

According to this invention, since the organic semiconductor layer is formed through a mixed liquid crystal state comprising an organic semiconductor material and a solvent, the formed organic semiconductor layer is good in orientation of the organic semiconductor material and can exhibit good charge mobility. Consequently, the organic semiconductor structure according to the present invention comprises an organic semiconductor layer having a phase (a smectic liquid crystal phase or a crystal phase), which is even and in a well aligned state in a wide service temperature range including room temperature, and, thus, can be used as organic semiconductor structures of organic transistors, organic EL elements, organic electronic devices, or organic solar cells.

Furthermore, the object of the present invention can be attained by an organic semiconductor device comprising at least a substrate, a gate electrode, a gate insulating layer, an organic semiconductor layer, a drain electrode, and a source electrode, characterized in that said organic semiconductor layer has been formed by the above method according to the present invention.

According to this invention, since an organic semiconductor layer, which has a high level of alignment of the organic semiconductor material and can exhibit good charge mobility, is provided, the organic semiconductor device can be used as organic transistors, organic EL elements, organic electronic devices, or organic solar cells.

Furthermore, according to the present invention, there is also provided use of the organic semiconductor structure according to the present invention, as an organic transistor, an organic EL element, an organic electronic device, or an organic solar cell.

### Effect of the Invention

In the method for organic semiconductor layer formation according to the present invention, since a well aligned smectic liquid crystal phase or crystal phase of an organic semiconductor material can be evenly and easily formed, an organic semiconductor layer having good charge mobility can easily be formed. According to this method, even for organic semiconductor materials of low molecular compounds and high molecular compounds, from which an organic semiconductor layer could not have hitherto been formed by coating without difficulties, phases (smectic liquid crystal phase or crystal phase) of these compounds can be formed in good molecule alignment by forming a coating film in a mixed liquid crystal state, and, thus, an organic semiconductor layer, which can exhibit stable charge mobility in a wide service temperature range including room temperature, can easily be formed.

The organic semiconductor structure and organic semiconductor device according to the present invention comprises an organic semiconductor layer having a phase (a smectic liquid crystal phase or a crystal phase), which is even and in a well aligned state in a wide service temperature range including room temperature, and, thus, can be used as organic semiconductor structures and organic semiconductor devices of organic transistors, organic EL elements, organic electronic devices, or organic solar cells.

### BRIEF DESCRIPTION OF THE DRAWINGS

FIG. 1 is a cross-sectional view of one embodiment of the organic semiconductor device according to the present invention;

FIG. 2 is a graph showing the results of measurement of hole mobility of an FET element with an organic semiconductor layer formed thereon;

FIG. 3 is a graph showing the results of measurement of hole mobility of an FET element with an organic semiconductor layer formed thereon;

FIG. 4 is a diagram showing the results of texture observation by a polarizing microscope and a heating stage using glass cells into which mixed liquid crystals with varied 8-QT-8 to xylene ratios have been poured; and

FIG. 5 is a diagram showing textures of 8-QT-8 alone free from xylene.

### DESCRIPTION OF REFERENCE CHARACTERS

101: organic semiconductor device,

11: substrate,

12: gate electrode,

13: gate insulating layer,

14: polymeric organic semiconductor layer,

15: drain electrode, and

16: source electrode.

### BEST MODE FOR CARRYING OUT THE INVENTION

The method for organic semiconductor layer formation, organic semiconductor structure, and organic semiconductor device according to the present invention will be described.

(Method for Organic Semiconductor Layer Formation)

The method for organic semiconductor layer formation according to the present invention comprises the steps of: forming a coating film in a mixed liquid crystal state using an organic semiconductor material and a solvent a mixture, which when mixed together, form a thermotropic mixed liquid crystal phase; and either cooling the coating film to a temperature at which the coating film does not form any mixed liquid crystal state, or removing the solvent while cooling the coating film, to form an organic semiconductor layer comprising a smectic liquid crystal phase or a crystal phase of said organic semiconductor material. Each step constituting the method will be described.

(Coating Film Formation Step)

In the step of forming a coating film, a coating film in a mixed liquid crystal state is formed using a mixture, which can exhibit a thermotropic mixed liquid crystal phase, prepared by mixing an organic semiconductor material with a solvent. The “mixed liquid crystal” is generally defined as (i) a mixture, which exhibits a liquid crystal phase, prepared by mixing a substance which exhibits a liquid crystal state with a substance which does not exhibit a liquid crystal state, (ii) a mixture, which exhibits a liquid crystal phase, prepared by mixing a substance which does not exhibit a liquid crystal state with a substance which does not exhibit a liquid crystal state, or (iii) a mixture, which exhibits a liquid crystal phase, prepared by mixing a substance which exhibits a liquid crystal state with a substance which exhibits a liquid crystal state. The “mixed liquid crystal state” refers to a mixed liquid crystal phase developed state. In the present invention, the organic semiconductor material may be or may not be a material that exhibits a liquid crystal state. Preferably, however, the organic semiconductor material is a compound that exhibits a liquid crystal state. The thermotropic mixed liquid crystal is a mixed liquid crystal having a phase transfer temperature, for example, a liquid crystal that, even when the organic semiconductor material is liquid crystalline, has a liquid crystal phase different from the liquid crystal phase exhibited by the organic semiconductor material. For example, as demonstrated in the working example which will be described later, in the mixed liquid crystal state, a smectic phase, which is different from the smectic phase exhibited by the organic semiconductor material per se, is exhibited.

The mixture comprises an organic semiconductor material, which develops a thermotropic mixed liquid crystal phase upon heating, and a solvent. When this requirement is satisfied, the type of the organic semiconductor material and the type of the solvent are not particularly limited. The organic semiconductor material may be or may not be liquid crystalline. Further, only one organic semiconductor material may be used, or alternatively two or more organic semiconductor materials may be used as a mixture. Even low molecular or high molecular compounds regarded as having low charge mobility, compounds, which can form a film only by vapor deposition, and compounds regarded as experiencing difficulties in film formation by coating in conventional organic semiconductor layer formation techniques, have a possibility of being utilizable as organic semiconductor materials by applying the present invention. Specific organic semiconductor materials are exemplified in the working example which will be described later. The organic semiconductor material, however, is not limited to those described in the working example, so far as the organic semiconductor material falls within the scope of the subject matter of the present invention.

The solvent is preferably one or at least two aromatic solvents selected from xylene, toluene, mesitylene, tetralin, monochlorobenzene, o-dichlorobenzene and the like. These aromatic solvents are considered to form the mixed liquid crystal phase, for example, through interaction with a skeleton of a π conjugated system possessed by the organic semiconductor material.

The mixture generally develops a thermotropic mixed liquid crystal phase upon heating. However, some types of organic semiconductor materials are already in a thermotropic mixed liquid crystal phase developed state without heating.

Examples of methods for the formation of a coating film in a mixed liquid crystal state include (i) a method which comprises heating the mixture to bring the state to a mixed liquid crystal state and then coating the mixture onto a substrate to form a coating film, (ii) a method which comprises coating the mixture onto a heated substrate to form a coating film and further to bring the coating film to a mixed liquid crystal state by the heat of the substrate, and (iii) a method which comprises coating the mixture onto a substrate and then heating the substrate to bring the coating film of the mixture to a mixed liquid crystal state.

The coating film is preferably formed in a mixed liquid crystal state comprising a nematic phase or a smectic phase by heating the mixture. In the mixed liquid crystal state, the phase transfer temperature is dropped by an impurity effect attained by mixing the organic semiconductor material with the solvent. Therefore, the coating film can be formed at a temperature below the film formation temperature of the organic semiconductor material per se. As a result, the coating film can be evenly formed in a coating area on the substrate. The coating film may be formed by any method without particular limitation, and any conventional coating or printing method may be adopted.

Substrates on which the coating film is to be formed include plastic substrates and glass substrates on which various films have been formed according to need depending upon applications of elements on which the organic semiconductor layer is to be formed (for example, organic transistors, organic EL elements, organic electronic devices, or organic solar cells).

(Organic Semiconductor Layer Formation Step)

In the step of forming an organic semiconductor layer, an organic semiconductor layer comprising a smectic liquid crystal phase or a crystal phase of the organic semiconductor material is formed by cooling the coating film to a temperature at which the coating film does not exhibit any mixed liquid crystal state, or by removing the solvent while cooling the coating film. In this step, since the solvent is removed by cooling the coating film in a mixed liquid crystal state or while cooling the coating film in a mixed liquid crystal state, the film after the removal of the solvent is an organic semiconductor layer in which a well aligned smectic liquid phase or crystal phase of the organic semiconductor material has been evenly formed.

The cooling to the temperature at which the mixed liquid crystal state is not exhibited is generally carried out, for example, by spontaneous standing to cool. In the cooling, the solvent in the coating film is removed, for example, by discharge or forcing-out from the phase. The film after the removal of the solvent is formed of the organic semiconductor material. In this case, since cooling is carried out while successively causing phase transitions from the heated mixed liquid crystal state, in the development of a smectic liquid crystal phase or crystal phase in the room temperature region, more regular alignment can be realized in the organic semiconductor material. As a result, an even and well aligned phase (a smectic liquid crystal phase or a crystal phase) can easily be formed, and, thus, the formed organic semiconductor layer can exhibit good charge mobility.

Whether the organic semiconductor layer exhibits a smectic liquid crystal phase or a crystal phase, is determined by the phase transition temperature of the mixed liquid crystal. When more stable properties in the room temperature region are contemplated, a crystal phase, which can realize alignment of higher regularity and does not cause a phase transition in the room temperature region, is desired.

(Organic Semiconductor Structure)

The organic semiconductor structure according to the present invention comprises an organic semiconductor layer formed by the above method. The organic semiconductor layer has a smectic liquid crystal phase or a crystal phase at least in the room temperature region. In the present invention, the room temperature region refers to a temperature range of −40° C. to 90° C. which is a common service temperature range of semiconductor elements such as organic TFTs.

In the formation of the organic semiconductor layer on the substrate, preferably, a coating film in a mixed liquid crystal state is formed on a substrate subjected to alignment treatment, and the assembly is then cooled as described above to form an organic semiconductor layer comprising a smectic liquid crystal phase or crystal phase of the organic semiconductor material. As a result, the alignment of the organic semiconductor material can be further improved. Substrates subjected to alignment treatment include substrates with a liquid crystal aligning layer formed of a polyimide material formed thereon and substrates with a liquid crystal aligning layer formed of a cured resin having very small concaves and convexes on its surface.

A first embodiment of the organic semiconductor structure according to the present invention comprises a substrate, a liquid crystal aligning layer, and an organic semiconductor layer stacked in that order. A second embodiment of the organic semiconductor structure according to the present invention comprises a substrate, an organic semiconductor layer, and a liquid crystal aligning layer stacked in that order. A third embodiment of the organic semiconductor structure according to the present invention comprises a substrate, a liquid crystal aligning layer, an organic semiconductor layer, and a liquid crystal aligning layer stacked in that order. In the present invention, a high level of alignment can be imparted to the organic semiconductor layer by forming the organic semiconductor layer in contact with the liquid crystal aligning layer.

As described above, in the organic semiconductor structure according to the present invention, since the organic semiconductor layer is formed through a mixed liquid crystal state comprising an organic semiconductor material and a solvent, the formed organic semiconductor layer is good in orientation of the organic semiconductor material and can exhibit good charge mobility. Consequently, the organic semiconductor structure according to the present invention comprises an organic semiconductor layer having a phase (a smectic liquid crystal phase or a crystal phase), which is even and in a well aligned state in a wide service temperature range including room temperature, and, thus, can be used as organic semiconductor structures of organic transistors, organic EL elements, organic electronic devices, or organic solar cells.

(Organic Semiconductor Device)

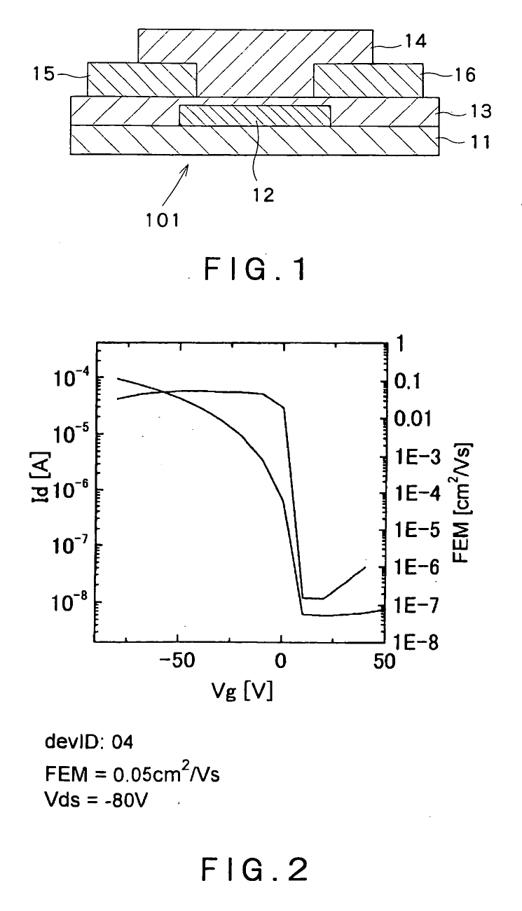

An organic semiconductor device 101 according to the present invention, for example, as shown in FIG. 1, comprises at least a substrate 11, a gate electrode 12, a gate insulating layer 13, an organic semiconductor layer 14, a drain electrode 15, and a source electrode 16. In this organic semiconductor device 101, the organic semiconductor layer 14 is formed by the above-described method for organic semiconductor layer formation according to the present invention.

Examples of the construction include a reversed stagger structure (not shown) comprising a substrate 11 and a gate electrode 12, a gate insulating layer 13, an aligned organic semiconductor layer 14, a drain electrode 15 and a source electrode 16, and a protective film 17 provided in that order on the substrate 11, or a coplanar structure (see FIG. 1) comprising a substrate 11 and a gate electrode 12, a gate insulating layer 13, a drain electrode 15 and a source electrode 16, an organic semiconductor layer 14, and a protective film (not shown) provided in that order on the substrate 11. The organic semiconductor device 101 having the above construction is operated in either an storage state or a deficiency state depending upon the polarity of the voltage applied to the gate electrode 12. Members for constituting the organic semiconductor device will be described in detail.

(Substrate)

The substrate 11 may be selected form a wide range of insulating materials. Examples of such materials include inorganic materials such as glasses and alumina sinters, polyimide films, polyester films, polyethylene films, polyphenylene sulfide films, poly-p-xylene films and other various insulating materials. The use of a film or sheet substrate formed of a polymer compound is very useful because a lightweight and flexible organic semiconductor device can be prepared. The thickness of the substrate 11 applied in the present invention is about 25 μm to 1.5 mm.

(Gate Electrode)

The gate electrode 12 is preferably an electrode formed of an organic material such as polyaniline or polythiophene, or an electrode formed by coating an electrically conductive ink. The electrode can be formed by coating an organic material or an electrically conductive ink and thus is advantageous in that the electrode formation process is very simple. Specific methods usable for the coating include spin coating, casting, pulling-up, and transfer and ink jet methods.

When a metal film is formed as the electrode, a conventional vacuum film formation method may be used for the metal film formation. Specifically, a mask film formation method or a photolithographic method may be used. In this case, materials usable for electrode formation include metals such as gold, platinum, chromium, palladium, aluminum, indium, molybdenum, and nickel, alloys using these metals, and inorganic materials such as polysilicon, amorphous silicone, tin oxide, indium oxide, and indium tin oxide (ITO). These materials may be used in a combination of two or more.

The film thickness of the gate electrode is preferably about 50 to 1000 nm although the film thickness varies depending upon the electric conductivity of the material for electrode. The lower limit of the thickness of the gate electrode varies depending upon the electric conductivity of the electrode material and the adhesive strength between the gate electrode and the underlying substrate. The upper limit of the thickness of the gate electrode should be such that, when a gate insulating layer and a source-drain electrode pair, which will be described later, are provided, the level difference part between the underlying substrate and the gate electrode is satisfactorily covered for insulation by the gate insulating layer and, at the same time, an electrode pattern formed thereon is not broken. In particular, when a flexible substrate is used, the balance of stress should be taken into consideration.

(Gate Insulating Layer)

As with the gate electrode 12, the gate insulating layer 13 is preferably formed by coating an organic material. Organic materials usable herein include polychloropyrene, polyethylene terephthalate, polyoxymethylene, polyvinyl chloride, polyvinylidene fluoride, cyanoethylpullulan, polymethyl methacrylate, polysulfone, polycarbonate, and polyimide. Specific examples of methods usable for coating include spin coating, casting, pulling-up, and transfer and ink jet methods. A conventional pattern process such as CVD may also be used. In this case, inorganic materials such as SiO₂, SiNx, and Al₂O₃ are preferred. These materials may be used in a combination of two or more.

Since the charge mobility of the organic semiconductor device depends upon the field strength, the thickness of the gate insulating layer is preferably about 50 to 300 nm. In this case, the withstand voltage is preferably not less than 2 MV/cm.

(Drain Electrode and Source Electrode)

The drain electrode 15 and the source electrode 16 are preferably formed of a metal having a large work function. The reason for this is that, in the conventional organic semiconductor material, since carriers for transferring charges are holes, these electrodes should be in ohmic contact with the organic semiconductor layer 14. The work function referred to herein is an electric potential difference necessary for withdrawing electrons in the solid to the outside of the solid and is defined as a difference in energy between a vacuum level and a Fermi level. The work function is preferably about 4.6 to 5.2 eV. Such materials include gold, platinum, and transparent electrically conductive films (for example, indium tin oxide and indium zinc oxide). The transparent electrically conductive film may be formed by sputtering or electron beam (EB) vapor deposition. The thickness of the drain electrode 15 and the source electrode 16 applied in the present invention is about 50 nm.

(Organic Semiconductor Layer)

The organic semiconductor layer 14 is a layer formed by the above-described method according to the present invention. The organic semiconductor layer 14 thus formed exhibits a smectic liquid crystal phase or a crystal phase having a high level of alignment at least in a temperature range including room temperature and has a characteristic effect that an even and large-area organic semiconductor device can be constructed.

When the organic semiconductor layer forming face is a gate insulating layer or a substrate, an aligning film can be integrated with the gate insulating layer or the substrate by subjecting the gate insulating layer or the substrate to rubbing treatment.

(Interlayer Insulating Layer)

An interlayer insulating layer is preferably provided in the organic semiconductor device 101. In forming the drain electrode 15 and the source electrode 16 on the gate insulating layer 13, the interlayer insulating layer is formed to prevent the contamination of the surface of the gate electrode 12. Accordingly, the interlayer insulating layer is formed on the gate insulating layer 13 before the formation of the drain electrode 15 and the source electrode 16. After the formation of the source electrode 15 and the drain electrode 16, the interlayer insulating layer in its part located above the channel region is completely or partly removed. The interlayer insulating layer region to be removed is preferably equal to the size of the gate electrode 12.

Materials usable for the interlayer insulating layer include inorganic material such as SiO₂, SiNx, and Al₂O₃ and organic materials such as polychloropyrene, polyethylene terephthalate, polyoxymethylene, polyvinyl chloride, polyvinylidene fluoride, cyanoethylpullulan, polymethyl methacrylate, polysulfone, polycarbonate, and polyimide.

(Other Embodiments of Organic Semiconductor Device)

Examples of the construction of the organic semiconductor device according to the present invention include (i) substrate/gate electrode/gate insulating layer (which functions also as liquid crystal aligning layer)/source-drain electrode/organic semiconductor layer (/protective layer), (ii) substrate/gate electrode/gate insulating layer/source-drain electrode/liquid crystal aligning layer/organic semiconductor layer (/protective layer), (iii) substrate/gate electrode/gate insulating layer (which functions also as liquid crystal aligning layer)/organic semiconductor layer/source-drain electrode/(protective layer), (iv) substrate/gate electrode/gate insulating layer (which functions also as liquid crystal aligning layer)/organic semiconductor layer/substrate with source-drain electrode patterned therein (which functions also as protective layer), (v) substrate/source-drain electrode/organic semiconductor layer/gate insulating layer (which functions also as liquid crystal aligning layer)/gate electrode/substrate (which functions also as protective layer), (vi) substrate (which functions also as aligning layer)/source-drain electrode/organic semiconductor layer/gate insulating layer/gate electrode/substrate (which functions also as protective layer), or (vii) substrate/gate electrode/gate insulating layer/source-drain electrode/organic semiconductor layer/substrate (which functions also as aligning layer).

In the organic semiconductor device, the organic semiconductor layer can easily be formed by a coating method according to the present invention.

### EXAMPLES

The following Examples further illustrate the present invention.

### Example 1

A mixture composed of 5,5′″-dioctyl-2,2′:5′,2″:5″,2′″-quaterthiophene (referred to as “8-QT-8”) having the following chemical formula and xylene as an aromatic solvent (8-QT-8 content: 0.5% by weight) was provided. Separately, a source/drain electrode (electrode material: gold, adhesive layer: chromium) was vapor deposited on a silicon wafer having a silicon oxide insulating film thickness of 3000 angstroms (300 nm), and the assembly was then subjected to surface treatment with phenyltrichlorosilane. This wafer was heated to about 90° C., and the above mixture heated to about 90° C. was spin coated (2000 rpm×10 sec) to form a coating film in a mixed liquid crystal state. Thereafter, the assembly was cooled to room temperature (25° C.) to remove xylene and thus to form an organic semiconductor layer comprising a crystal phase. Thus, an FET element with an organic semiconductor layer formed thereon was prepared. The properties of the FET element was evaluated with 237 HIGH VOLTAGE SOURCE MEASURE UNIT manufactured by KEITHLEY. The charge mobility of holes was 5.0×10⁻² cm²/Vs, and the ON/OFF ratio was about 10⁴. FIG. 2 is a graph showing the results of the measurement of hole mobility of the FET element with an organic semiconductor layer formed thereon.

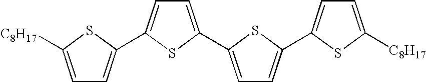

### Example 2

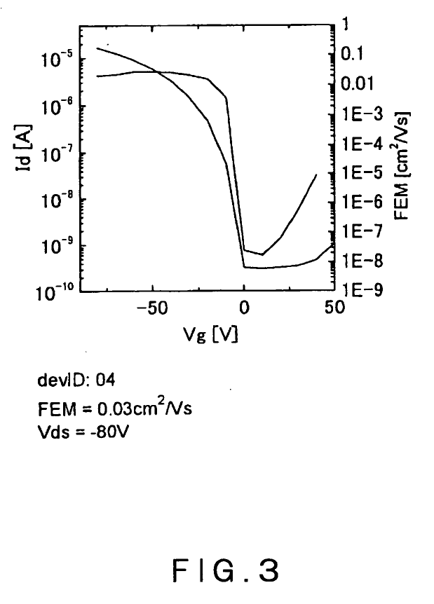

A mixture composed of 5,541 ″-didecyl-2,2′:5′,2″:5″,2′″:5′″,2″″-quinquetthiophene (referred to as “10-5T-10”) having the following chemical formula and mesitylene as an aromatic solvent (10-5T-10 content: 0.5% by weight) was provided. Separately, a source/drain electrode (electrode material: gold, adhesive layer: chromium) was vapor deposited on a silicon wafer having a silicon oxide insulating film thickness of 3000 angstroms (300 nm), and the assembly was then subjected to surface treatment with phenyltrichlorosilane. This wafer was heated to about 90° C., and the above mixture heated to about 90° C. was spin coated (2000 rpm×10 sec) to form a coating film in a mixed liquid crystal state. Thereafter, the assembly was cooled to room temperature (25° C.) to remove mesitylene and thus to form an organic semiconductor layer comprising a crystal phase. Thus, an FET element with an organic semiconductor layer formed thereon was prepared. The properties of the FET element was evaluated with 237 HIGH VOLTAGE SOURCE MEASURE UNIT manufactured by KEITHLEY. The charge mobility of holes was 3.0×10⁻² cm²/Vs, and the ON/OFF ratio was about 10^{5.} FIG. 3 is a graph showing the results of the measurement of hole mobility of the FET element with an organic semiconductor layer formed thereon.

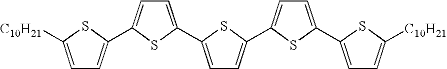

### Example 3

A mixture composed of 5,5′″-dioctyl-2,2′:5′,2″:5″,2′″-quaterthiophene (referred to as “8-QT-8”) and xylene as an aromatic solvent (8-QT-8:xylene mixing ratio (% by weight)=1:3 and 1:1) was provided. These two mixtures were observed for texture under a polarization microscope (BH2-UMA, manufactured by Olympus Corporation) with a heating stage (FP82HT and FP80HT, manufactured by METTLER-TOLEDO K.K.).

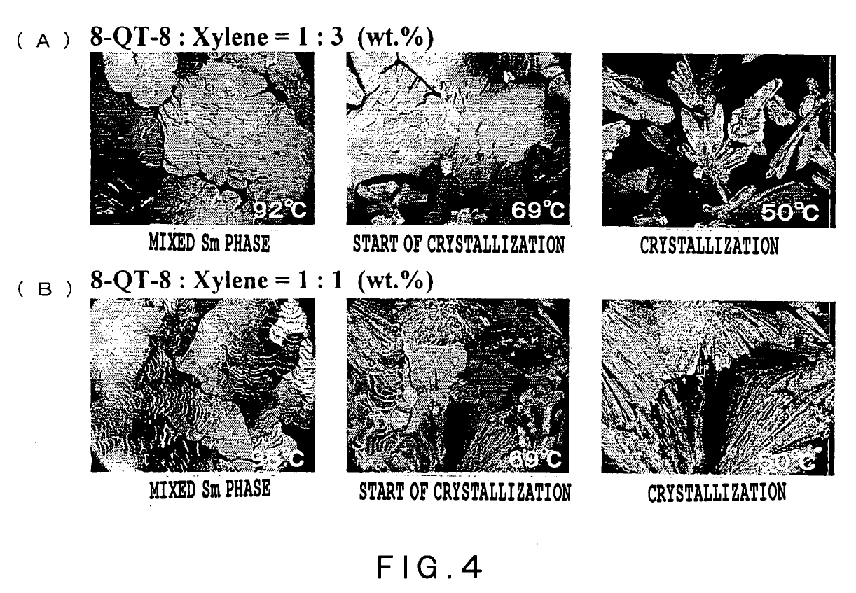

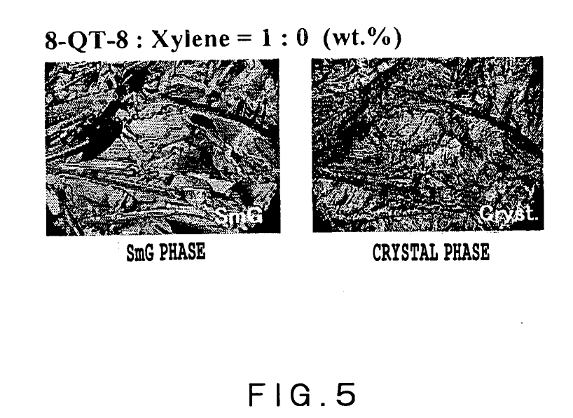

FIG. 4 shows the results of observation of the texture under a polarization microscope with glass cells into which the mixed liquid crystals with varied 8-QT-8:xylene content ratios have been poured. FIG. 4(A) shows the texture at each temperature of the mixed liquid crystal at 8-QT-8:xylene=1:3 (% by weight), and FIG. 4(B) shows the texture at each temperature of the mixed liquid crystal at 8-QT-8:xylene=1: 1 (% by weight). For comparison, the texture of xylene-free 8-QT-8 is shown in FIG. 5. As is apparent from these textures, the texture of the mixed liquid crystals was different from the texture of 8-QT-8 only and appears to be a mixed Sm phase.

The phase transition temperature of the mixed liquid crystal at 8-QT-8:xylene=1:3 (% by weight) was crystal phase/69° C./mixed Sm phase/105° C./isotropic phase. On the other hand, the phase transition temperature of the mixed liquid crystal at 8-QT-8:xylene=1:1 (% by weight) was crystal phase/69° C./mixed Sm phase/140° C./isotropic phase. The phase transition temperature of 8-QT-8 was crystal phase/80.6° C./SmG phase/175.6° C./isotropic phase. For the mixed liquid crystal, a phase transition temperature drop was observed due to an impurity effect attained by the presence of xylene. The temperature indicated between the phases refers to the phase transition temperature between the phase indicated on the left side and the phase indicated on the right side. For example, “crystal phase/69° C./mixed Sm phase” means that the phase transition temperature between the crystal phase and the mixed Sm phase is 69° C.

1. A method for the formation of an organic semiconductor layer comprising the steps of:
forming a coating film in a mixed liquid crystal state using an organic semiconductor material and a solvent a mixture, which when mixed together, form a thermotropic mixed liquid crystal phase; and
either cooling the coating film to a temperature at which the coating film does not form any mixed liquid crystal state, or removing the solvent while cooling the coating film, to form an organic semiconductor layer comprising a smectic liquid crystal phase or a crystal phase of said organic semiconductor material.

2. The method for the formation of an organic semiconductor layer according to claim 1, wherein said coating film is formed by heating said mixture and coating the heated mixture.

3. The method for the formation of an organic semiconductor layer according to claim 1, wherein said solvent is one or at least two aromatic solvents selected from xylene, toluene, mesitylene, tetralin, monochlorobenzene, o-dichlorobenzene and the like.

4. An organic semiconductor structure comprising an organic semiconductor layer formed by a method according to claim 1, said organic semiconductor layer comprising a smectic liquid crystal phase or a crystal phase at least in a room temperature region.

5. An organic semiconductor device comprising at least a substrate, a gate electrode, a gate insulating layer, an organic semiconductor layer, a drain electrode, and a source electrode, said organic semiconductor layer being formed by a method according to claim 1.

6. Use of an organic semiconductor structure according to claim 4, as an organic transistor, an organic EL element, an organic electronic device, or an organic solar cell.
